(19) United States
(12) Patent Application Publication
(10) Pub. No.: US 2026/0354051 A1
(43) Pub. Date: Nov. 5, 2026

(54) N-Type Carbon-Based Semiconductor Substrates and Methods of Preparing Same

(71) Applicant: ZERO RESISTANCE (PTY) LTD, Pretoria (ZA)

(72) Inventors: Andrè Christiaan Cloete, Pretoria (ZA); Willem Tobias Myburgh, Pretoria (ZA); Jacques Christiaan Badenhorst, Johannesburg (ZA)

(21) Appl. No.: 19/115,547

(22) PCT Filed: Feb. 8, 2024
(86) PCT No.: PCT/IB2024/051150

§ 371 Date: Mar. 26, 2025

Related U.S. Application Data
(60) Provisional application No. 63/484,075, filed on Feb. 9, 2023.

(51) Int. Cl. H10P 14/20; C30B 25/16; C30B 29/04; C30B 31/18; H10P 14/24

(52) U.S. Cl. CPC H10P 14/3406; C30B 25/165; C30B 29/04; C30B 31/18; H10P 14/24; H10P 14/3438

(57) ABSTRACT

The invention describes a method of producing a semiconductor substrate by utilising a body of sp3 carbon allotrope, such as diamond or Diamond-Like Carbon and processing the body with electron donor ions to form an n-type semiconductor 5 substrate. The donor ions have an ionic radius within 15% larger or smaller than the atom ionic radius of the sp3 carbon allotrope. The invention further extends to a semiconductor substrate and semiconductors having a substrate as prepared in accordance with the invention.

### CROSS-REFERENCE TO RELATED APPLICATION

This application is a U.S. National Stage application under 35 U.S.C. [symbol] 371 of International Application PCT/IB2024/051150 (published as WO 2024/1660231 A1), filed Feb. 24, 2024, which claims the benfit of priority to U.S. Application No. 63/484,075, file Feb. 8, 2023. Benefit of the filing date of each of these prior applications is hereby claimed. Each of these prior applications is hereby incorporated by reference in its entirety.

### INTRODUCTION TO THE INVENTION

This invention relates to electrical conductors, more specifically n-type carbon-based semiconductors and methods for preparing carbon-based semiconductors and substrates suitable for use in semiconductors.

### BACKGROUND TO THE INVENTION

Diamond is a material with semiconductor properties that are superior to silicon (Si), germanium (Ge) or gallium arsenide (GaAs), which are used in conventional semiconductors. In particular, diamond provides a higher band gap, higher breakdown voltage and greater saturation velocity, which produces a substantial increase in its cut-off frequency and a maximum operating voltage compared to devices fabricated from Si, Ge or GaAs, for example. Furthermore, diamond has the highest thermal conductivity of any solid at room temperature and excellent conductivity (after doping) over a temperature range up to and beyond 400° Celsius due to the very strong sp3 carbon bond building the crystal. Diamonds, and any allotrope of carbon containing sp3 carbon bonds, therefore holds potential for efficient semiconductor operation at high power.

The advantages of diamond as a semiconductor have not been fully exploited for various reasons. Although natural diamonds may be of device quality, they are of limited supply and size and are fairly expensive. Furthermore, most natural diamonds are insulators, and thus introduction or doping of electrically active impurities is required to render them useful as semiconductors. Doping by ion implantation has however proved to be difficult in diamond, due to the strong carbon bonds preventing penetration of ion impurities.

All known prior art implantation doping of diamonds, have been high energy ion implantation, such as done routinely with silicon to produce semiconductors which are widely used in commerce. High energy ion implantation, however, causes lattice damage to the crystal. This damage is partially reparable, because the annealing temperature of diamond is below its graphitic conversion point. Complete conversion of the top 20% of the diamond film to graphitic material appears to be unavoidable. Such damage occurs even when the implanted atom is smaller than carbon, like an implanted nitrogen ion. It is likely that the damage would be much greater with doped ions like sodium or phosphorus, which are larger than carbon.

A second way to produce device quality diamonds is to synthesize them on a suitable substrate by a Chemical Vapor Deposition (CVD) process. In this technique, a gaseous mixture including a carbon supply, usually provided by methane and hydrogen, is pyrolized, or injected into a high frequency plasma, above the substrate surface. In this respect, the substrate is either a very thin mono crystal diamond or small diamond crystals spread over another host substrate. Radicals containing carbon react to produce diamond crystals on the substrate, while the hydrogen present is converted to atomic hydrogen, which preferentially etches away graphite and thereby leaves a film which is predominately diamond. This method allows for the possibility of doping by introducing electrically active impurities into the bulk environment above the substrate which are then bonded in the diamond lattice as the lattice is synthesized. The addition of oxygen has however, to date, only been included in small percentages and in a constant manner/flow. Moreover, any additional gas used in different diamond processes, for example boron, has always been included at a constant flow rate, to affect real-time doping.

Using the prior art teachings, boron and oxygen can be substitutionally grown into the diamond lattice reliably at low pressure. Boron has useful electrical activity, providing p-type material, while nitrogen has been found to be electrically inactive when grown in. The prior art has made some efforts at producing n-type diamond through the introduction of phosphorus and alkali metals. Control over doping levels in the prior art has been very crude because chemical incorporation of impurities appears to be strongly dependent upon growth additions and the dopant feed stocks form long lived volatile residues in the growth chamber. No known prior art allows the reliable production of n-type diamond doped with any desirable material without substantial lattice damage (implantation).

Although diamond p-type and n-type impurities and techniques do exist today, a complimentary diamond semiconductor process, does not exist with the known impurities that are available.

### OBJECT OF THE INVENTION

It is accordingly an object of the present invention to create n-type substrates from mono and poly crystal diamond and any other allotrope form of carbon that contains sp3 carbon bonds for use in the manufacture of electronic and optical devices, in particular semiconductor devices in diamond and Diamond-based Carbon (DLC).

### SUMMARY OF THE INVENTION

In accordance with the invention there is provided a method of producing a semiconductor substrate comprising the steps of:
utilising a body of sp3 carbon allotrope; and
processing the body with electron donor ions, wherein the donor ions have an ionic radius within 15% larger or smaller than the atom ionic radius of the sp3 carbon allotrope, to operatively form an n-type semiconductor substrate.

The body of the sp3 carbon allotrope may be diamond; and the step of processing the body may include growing the diamond by a Chemical Vapor Deposition (CVD) process, while a dopant, preferably oxygen, is intermittently added to hydrogen and methane gasses during said CVD process such that the oxygen dopant in the diamond is grown in layers through the bulk of the substrate during the CVD process.

The oxygen dopant may be intermittently added as less than 1:200 of the total introduced gas volume; and the methane to hydrogen ratio may be 1:10 or less.

The processing may be provided such that the temperature of the substrate on which the diamond precipitates, ranges from 900 to 1100 degrees Celsius, preferably 950 to 1000 degrees Celsius.

The invention further includes the step of using the diamond for creating an n-type epi-layer.

In accordance with another aspect of the invention, the body of the sp3 carbon allotrope may be a Diamond-Like Carbon (DLC) film; and the step of processing the body may comprise growing the DLC film by Chemical Vapor Deposition (CVD) process in the presence of oxygen ions such that oxygen is incorporated in the forming of sp2 and sp3 bonds, creating n-type dopants through the bulk of the DLC.

The invention further includes the step of using the DLC for creating an n-type epi-layer.

In accordance with a yet further aspect of the invention, the body of the sp3 carbon allotrope may be processed by implanting an impurity, preferably either one of oxygen or nitrogen, into the body such that the implanted impurity is used as an n-type active impurity.

The invention further provides for the step of implantation to be provided at low energy with concurrent annealing.

The step of implantation may occur during a Chemical Vapor Deposition (CVD) process wherein the process is alternated between growth and implantation, such that a growth layer reaches a thickness equal to the implantation depth to be administered whereafter the implantation is then administered.

The body of the sp3 carbon allotrope may be diamond or Diamond-Like Carbon (DLC).

The invention further provides for step of using the diamond or DLC for creating an n-type epi-layer.

In accordance with another aspect of the invention there is provided a semiconductor substrate as prepared in any one of the aforementioned aspects.

In accordance with a yet further aspect of the invention there is provided a semiconductor having a substrate as prepared in any one of the aforementioned aspects.

### BRIEF DESCRIPTION OF THE ACCOMPANYING DRAWINGS

The invention will now be described by way of example only with reference to the accompanying drawing wherein:

FIG. 1 illustrates a diode, created with Boron p-type and Nitrogen n-type impurities in a diamond crystal.

### DESCRIPTION OF PREFERRED EMBODIMENTS OF THE INVENTION

The invention describes a method of producing a semiconductor substrate which generally includes the steps of utilising a body of sp3 carbon allotrope and processing the body, by means of doping by growing in or implanting the body with electron donor ions to form an n-type semiconductor substrate. These donor ions include dopant ions which are regarded as a defect in the solid of the sp3 carbon allotrope and which has an ionic radius within 15% larger or smaller than the atomic ionic radius of the sp3 carbon allotrope solid. These dopant ions are also electron donors to operatively form the n-type semiconductor substrate. Typical examples of suitable donor/dopant ions in this description include oxygen and nitrogen, but are not limited to these only. Therefore, any suitable electron donor ions can be used in accordance with the invention if the donor ions comply with the aforesaid characteristics in relation to the sp3 carbon allotrope utilised—this can be identified and will be within the competence of a skilled artisan.

The semiconductor substrate may then be further processed and used as known in the semiconductor art. The invention thus further includes semiconductor substrates as prepared in accordance with this invention, as well as semiconductors incorporating these substrates.

In embodiments of this invention, the sp3 carbon allotrope includes diamond and Diamond-Like Carbon (DLC) but may be further extended to other suitable sp3 carbon allotropes.

With current known methods of doping oxygen into diamond, in the gas phase, in a microwave plasma, the oxygen is doped in such a way that only allows conduction in the termination layer of the diamond. An alternative method for oxygen doping is also in practice. However, by this second method of ion implantation, oxygen has got a limited depth of implantation and has got a much lower conductance than the current invention's doping method. For a semiconductor, higher conductance during forward bias, is very important.

In a first example embodiment of the invention, the present invention has been developed to provide a method whereby the oxygen concentration in diamond can be controlled precisely during the synthesis of oxygen-doped diamond by a microwave plasma method, increasing the diamond's bulk conductance. During this doping, the oxygen is doped in the diamond lattice and the conductance is not being generated in the bulk from oxygen and hydrogen termination bond, but from oxygen donor electrons as described below.

Oxygen is introduced into the diamond body as an impurity in the gas phase during synthesis of diamond, to create n-type semiconducting characteristic in the diamond. During the synthesis of oxygen-doped diamond by Chemical Vapor Deposition (CVD) process, oxygen is introduced into a volatile reaction gas comprising hydrogen and methane. The oxygen comprises around 0.5 percent of the sum of the hydrogen, methane and oxygen, as a starting point. The oxygen gets injected at a variable concentration flow rate. The oxygen gets decomposed into ions in the plasma, in the CVD chamber. Subsequently, physics determines how the oxygen ions get incorporated into the diamond lattice as the crystal grows. A single crystal or polycrystalline thin film of diamond, containing oxygen atoms, is grown on a diamond seed substrate placed in the reactor creating an array of doped sites as the crystal grows. Sometimes a silicon wafer is also used as a substrate covered with nano diamonds, so as to allow the growth of a poly crystal thin film diamond over the whole wafer area.

The oxygen percentage used for the synthesis of the present embodiment of the invention is preferably less than 1:200 of the total introduced gas volume. As mentioned, gases introduced are oxygen, methane and hydrogen. The ratio of the methane to hydrogen in the reaction gas is preferably 1:10 or less. The temperature of the substrate on which diamond precipitates, is usually from 900 to 1100 °C, preferably from 950 to 1000 °C.

It will also be understood that, as mentioned, the ratio of oxygen to the other two gases, is important. For one, there is a solid solubility, placing a limit on the amount of oxygen that can naturally be incorporated in the diamond lattice. Breaching this limit during CVD, might influence the CVD process. More likely it will form other molecules that will be pumped out. To force more oxygen into the lattice with different methods, could damage the structure such that the diamond character is changed. Also, if the oxygen impurity concentration is too high, the semiconductor character will be replaced with metallic conduction character. When performed correctly, oxygen will form an epi layered n-type diamond material that will make for easier semiconductor processing near the surface, also allowing creation of vertical BJT structures in the bulk.

To let a mono diamond single crystal film grow, it is preferred to use a substrate of hetero-epitaxially grown diamond or single crystal diamond. Any one of the {111} face, the {110} face and the {100} face may be used. The latter is preferred. As mentioned, poly crystal also works.

This will create n-type epi layer diamond wafer, as the basis (i.e., substrate) for a diamond semiconductor process.

In a second embodiment of the invention, by extending the above procedure of oxygen impurity addition during diamond synthesis, the invention further provides to include the oxygen impurity addition during synthesis of Diamond-Like Carbon (DLC) as a well-known allotrope of carbon that contains sp3 bonds, to provide a cheaper alternative to “diamond-tronics”, and flexibility with which transistor circuits could be created. Since DLC creation is a low temperature process, the possibility and advantage provide that a semiconductor coating could be sputtered onto many surfaces. DLC has previously not been used for anything other than a coating.

It is to be understood that an important parameter during the DLC creation is the background pressure. If the oxygen gets added incorrectly, it could impact negatively on the background pressure, which will interfere with the forming of the required sp3 carbon bonds. Sp3 carbon bonds, normally, contributes at least 60% to most DLC creation. These bonds are the bonds that form a diamond and make DLC hard. The rest consist out of sp2 bonds. Sp2 bonds are weak and form graphite. By preventing the forming of sp3 bonds, DLC will not form. The background pressure is thus very important, to control.

This background pressure is the reason why an ion gun will not be suitable for use during DLC forming concurrently, as these ions will hit the target and thus disturb the pressure with no sp3 bonds forming. A homogeneous pressure is therefore required throughout the DLC forming chamber.

In accordance with a third embodiment of the invention, an impurity, such as oxygen or nitrogen is implanted into the body such that the implanted impurity may be used as an n-type impurity. In this regard, the only implantation method left to be able to grow an oxygenated n-type epi layer DLC, that will not interfere with the sp3 bonds forming, is by alternating oxygen implantation and DLC growth. In this instance, a certain thickness is grown and followed by implanting that particular thickness' equivalent depth with the appropriate implantation voltage, keeping damage to a minimum, so that the next growth cycle (deposition) can continue unhindered. This n-type epi layer DLC, is an integral part of creating DLC-tronics. Creating a semiconductor without a prepared epi layer basis, becomes more complicated and expensive, for certain structures.

Now with the epi layer wafer formed in diamond or DLC, this aspect will address the precise processing required for the forming of n-channel FET or BJT types. Implantation is a surface technique that lends itself to the creation of shallow semiconductor circuits in the chosen semiconductor material—in the present invention, diamond. Since being cubic, the diamond lattice creates a similar problem to silicon, in that perpendicular implantation to the surface will allow channelling to occur and the implanted ions end up too deep or going through the material.

Another aspect to consider is the size of the nitrogen ions. Being almost the same size as carbon in the diamond crystal, it is easy for these implanted particles to fit between the carbon atoms in the lattice and travel straight through the diamond. Also, being a lightweight ion, nitrogen does not easily make an impact on the bonded carbon. This light weight is not overcome with more momentum, because then the particle will definitely travel through the diamond. As the ionic radius of nitrogen is within 15% larger or smaller than the diamond or DLC's atomic ionic radius, nitrogen is a suitable donor ion for this invention.

The invention thus uses angled implantation, (together with a thermodynamic lattice distortion (vibration)), to create a better chance for a nitrogen ion to hit a diamond carbon atom and get bounded into the lattice as an impurity that is electrically active with an acceptable activation energy. The 7-degrees from perpendicular, used in the silicon semiconductor field, is a good starting point. However, at this angle with the implantation voltages used by those skilled in the art of implantation, and with no lattice distortion, will not deliver acceptable results. The required result as determined by one's design, should lead to an optimal choice of implantation angle, implantation energy and target temperature.

One example could be an implantation angle of 30 degrees from the perpendicular, with an implantation energy of 10 kEV and the diamond heated to 300 degrees Celsius.

The example embodiments one to three described above therefore form an n-type semiconductor substrate which may be further processed as per the example below. However, it will be understood that the particular design can be varied in accordance with a particular purpose and will be well within the competence of a skilled artisan.

For example, the n-type epi layer, with the higher concentration n-type nitrogen implantation, paired with the known art of boron p-type impurity implantation in the diamond lattice, will be used in similar ways to other semiconductor processes.

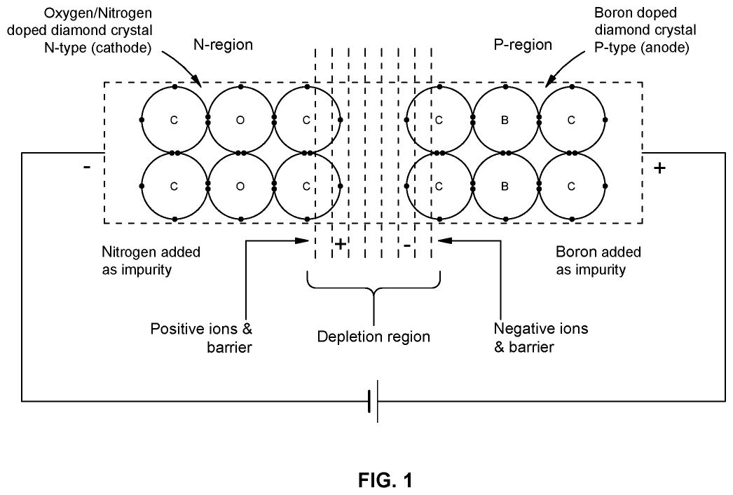

Creating wells, biasing certain areas, creating vertical BJT structures for reference or power circuitry and horizontal structures for the creation of a whole host of semiconductor devices. FIG. 1 illustrates a diode, created with boron p-type and nitrogen n-type impurities in a diamond crystal.

When using DLC instead of diamond, as the basis upon which a person skilled in the art wishes to create a semiconductor circuitry, implantation angle and low energy do not really contribute to the success of the impurity implantation. The reason being that the DLC does not have a lattice structure as it is not a crystal. Channelling is thus no problem. DLC consists out of areas that might have a nano crystal structure at a point, but in general it is amorphous. With this DLC's structure, higher implantation energy would be required to get higher implantation penetration because of higher material disorder.

Semiconductors are made from crystals that do not contain impurities, so one can precisely control the creation of one's electronic circuits. As far as diamond is concerned, it is also a crystal. DLC consist out of different ratios of sp2 and sp3 bonds. The purest one, Ta—C (tetrahedral amorphous carbon), consists only of sp3 C—C bonds and would be the best to use for semiconductor processing. As long as the DLC material is an insulator, it can be implanted to create electronic circuitry. If the DLC is of a lower grade that is conductive, it is not adequate for semiconductor processing as leaking and shorting of structure will make it unusable.

Using this DLC after oxygen addition describe above, to create a DLC n-type epi layer wafer, one will be able to implant n-type nitrogen by controlling time and implantation energy and also p-type boron by controlling time and implantation energy, to create the desired semiconductor circuitry. One can also create wells and vertical circuitry, not just horizontal circuitry, using semiconductor known art techniques. It is to be understood that creating DLC is a “cold” process. To do nitrogen implantation layer by layer (raster fashion) or only in the top layer, the DLC has to be at an elevated temperature (above 300 Celsius). Implantation is only effective when the DLC material is heated.

It is accordingly asserted that the disadvantages of the prior art are overcome or at least alleviated by the current invention. The current invention therefore provides for the ability to create an n-type substrate of sp3 carbon allotropes such as diamond and DLC for use in the manufacture of electronic and optical devices, in particular semiconductor devices in diamond and DLC. This provides, for example, the application of a higher central processing unit operating frequency. The invention further provides the benefits of a semiconductor which has reduced cooling requirements; can operate at higher temperatures and is much smaller than conventional semiconductor circuits.

The description is presented by way of example only in the cause of providing what is believed to be the most useful and readily understood description of the principles and conceptual aspects of the invention. In this regard, no attempt is made to show structural details of the invention in more detail than is necessary for a fundamental understanding of the invention. The words which have been used herein are words of description and illustration, rather than words of limitation.

1. A method of producing a semiconductor substrate comprising the steps of:
utilising a body of sp3 carbon allotrope; and
processing the body with single impurity electron donor ions, wherein the donor ions have an ionic radius within 15% larger or smaller than an atom ionic radius of the sp3 carbon allotrope, to operatively form an n-type semiconductor substrate.

2. The method of claim 1,
wherein the body of the sp3 carbon allotrope is diamond, and
wherein the step of processing the body comprises growing the diamond by a Chemical Vapor Deposition (CVD) process, while a dopant is intermittently added to hydrogen and methane gasses during said CVD process such that the dopant in the diamond is grown in layers through a bulk of the semiconductor substrate during the CVD process.

3. The method of claim 2,
wherein oxygen is the dopant,
wherein the oxygen dopant is intermittently added as less than 1:200 of a total introduced gas volume, and
wherein a ratio of methane to hydrogen ratio is 1:10 or less.

4. The method of claim 2 or 3, wherein the processing is provided such that a temperature of the semiconductor substrate, on which the diamond precipitates, ranges from 900 to 1100 degrees Celsius.

5. The method of claim 2, further comprising:
creating an n-type epi-layer by using the diamond.

6. The method of claim 1,
wherein the body of the sp3 carbon allotrope is a Diamond-Like Carbon (DLC) film,
wherein the step of processing the body comprises growing the DLC film by a Chemical Vapor Deposition (CVD) process in the presence of oxygen ions such that oxygen is incorporated in sp2 and sp3 bonds, and
wherein oxygen in the sp2 and sp3 bonds forms n-type dopants through a bulk of the DLC.

7. The method of claim 6, further comprising:
forming, using the DLC, an n-type epi-layer.

8. The method of claim 1,
wherein the step of processing the body with single impurity ions comprises:
implanting an impurity into the body such that the implanted impurity, after reaction in the semiconductor substrate, acts as an n-type active impurity when electrically biased.

9. The method of claim 8,
wherein the step of implanting the impurity is provided at low energy with concurrent annealing.

10. The method of claim 8 or 9,
wherein the step of implanting the impurity occurs during a Chemical Vapor Deposition (CVD) process wherein the process is alternated between growth and implantation, such that a growth layer reaches a thickness equal to an implantation depth to be administered whereafter the implantation is then administered.

11. The method of claim 10, wherein the body of the sp3 carbon allotrope is diamond or Diamond-Like Carbon (DLC).

12. The method of claim 11, including the step of using the diamond or DLC for creating an n-type epi-layer.

13. A semiconductor substrate as prepared in claim 1.

14. A semiconductor having a substrate as prepared in claim 1.

15. The method of claim 4,
wherein the temperature of the semiconductor substrate on which the diamond precipitates ranges from 950 to 1000 degrees Celsius.

16. The method of claim 8,
wherein the impurity is oxygen or nitrogen.
